(19) United States
(12) Patent Application Publication
(10) Pub. No.: US 2026/0371763 A1
(43) Pub. Date: Nov. 19, 2026

(54) IMAGE SENSORS AND METHOD OF MANUFACTURING THE SAME

(71) Applicant: Taiwan Semiconductor Manufacturing Company, Ltd., Hsinchu (TW)

(72) Inventors: Bo Kai Wang, Taichung City (TW); Szu-Ying CHEN, Miaoli (TW)

(73) Assignee: Taiwan Semiconductor Manufacturing Company, Ltd., Hsinchu (TW)

(21) Appl. No.: 19/210,935

(22) Filed: May 16, 2025

(51) Int. Cl. H10F 39/00; H10F 39/12; H10F 39/18

(52) U.S. Cl. CPC H10F 39/807; H10F 39/014; H10F 39/182; H10F 39/199; H10F 39/811

(57) ABSTRACT

An optical device and a method of fabricating the same are disclosed. The optical device includes a substrate with a first surface and a second surface opposite to the first surface, an array of pixel structures disposed in the substrate, an interconnect structure with a metal line disposed on the first surface of the substrate, and an isolation structure. The isolation structure includes an inter-pixel isolation portion disposed between adjacent pixel structures in the array of pixel structures and a peripheral isolation portion surrounding the array of pixel structures and disposed on the metal line of the interconnect structure.

### BACKGROUND

Image sensors are used to sense incoming visible or non-visible radiation, such as visible light and infrared light. Complementary metal-oxide-semiconductor (CMOS) image sensors (CIS) and charge-coupled device (CCD) sensors are used in various applications, such as digital still cameras, mobile phones, tablets, and goggles. These image sensors utilize an array of pixel structures that absorb (e.g., sense) an incoming radiation and convert it into electrical signals. An example of an image sensor is a back-side illuminated (BSI) image sensor, which detects radiation from a “back-side” of a substrate of the BSI image sensor.

### BRIEF DESCRIPTION OF THE DRAWINGS

Aspects of this disclosure are best understood from the following detailed description when read with the accompanying figures.

FIGS. 1-10 illustrate different cross-sectional views of a BSI image sensor, in accordance with some embodiments.

FIG. 11 is a flow diagram of a method for fabricating a BSI image sensor, in accordance with some embodiments.

FIGS. 12-19 illustrate cross-sectional views of a BSI image sensor at various stages of its fabrication process, in accordance with some embodiments.

FIGS. 20-24 illustrate cross-sectional views of another BSI image sensor at various stages of its fabrication process, in accordance with some embodiments.

FIGS. 25-29 illustrate cross-sectional views of another BSI image sensor at various stages of its fabrication process, in accordance with some embodiments.

FIGS. 30-35 illustrate cross-sectional views of another BSI image sensor at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20 % of the value (e.g., ±1%, ±2%, ±3%, ±4%, ±5%, ±10%, ±10-15%, ±15~20% of the value). These values are merely examples and are not intended to be limiting. The terms “about” and “substantially” can refer to a percentage of the values as interpreted by those skilled in relevant art(s) in light of the teachings herein.

A BSI image sensor includes an array of pixel structures (also referred to as “pixel units,” “pixel cells,” “pixel regions,” and “pixels”) on a substrate (e.g., a semiconductor substrate). The pixel structures can include radiation-sensing devices, which are configured to receive (or absorb) an electromagnetic radiation (e.g., infra-red radiation) projected toward a back-side of the substrate and convert photons from the received radiation to electrical signals. The electrical signals are subsequently distributed to processing components attached to the BSI image sensor.

In the BSI image sensor, an interconnect structure is disposed on a front-side of the substrate to electrically connect the pixel structures to the processing components and to distribute the electrical signals generated within the pixel structures to appropriate processing components. Color filters and micro-lenses in the BSI image sensor are disposed on the back-side of the substrate to collect light with minimal or no obstructions from the elements of the interconnect structure and/or the pixel structures. As a result, BSI image sensors have improved performance under low light conditions and higher quantum efficiency (QE) (e.g., photon to electron conversion percentage) than front-side illuminated image sensors.

The BSI image sensor also includes an isolation structure (also referred to as a “deep trench isolation (DTI) structure”) disposed in the substrate and surrounding the radiation-sensing devices to reduce or prevent electrical and/or optical cross-talk between adjacent radiation-sensing devices. Cross-talk can occur when light and/or current from one radiation-sensing device leak into adjacent radiation-sensing devices, thereby causing the adjacent radiation-sensing devices to falsely sense light. Such cross-talk can reduce the precision and the quantum efficiency of the BSI image sensor.

One of the challenges of forming BSI image sensors is preventing current leakage through defects formed on the surfaces of the isolation structure. These defects (e.g., dangling bonds) can be a result of processes (e.g., etching processes) used to form the isolation structure and can trap carriers, such as electrons. The trapped carriers can produce leakage current, which is problematic for BSI image sensors. For example, with a sufficient amount of leakage current, radiation-sensing devices in the pixel structures can falsely detect light, even when the BSI image sensor is placed in an optically dark environment. In such a situation, the leakage current is referred to as a “dark current,” and the pixel structure with the radiation-sensing device is referred to as a “white pixel.” Dark currents and white pixels are forms of undesirable electrical cross-talk, which degrade the performance of the BSI image sensor.

One of the approaches for reducing such leakage current has been the use of high-k dielectric liners on the surfaces of the isolation structure. The negative fixed charge of the high-k dielectric liners cause holes to accumulate on the isolation structure, which can recombine with the electrons trapped in the surface defects of the isolation structure and reduce the leakage current. However, continued scaling down of BSI image sensors to meet the ever-growing demand for smaller devices has led to the reduction in the dimensions of high-k dielectric liners, which resulted in the reduction of the negative fixed charge of the high-k dielectric liners. Such reduction in the negative fixed charge increased the challenges of accumulating sufficient holes on the isolation structure for preventing leakage current.

To overcome the abovementioned challenges, the present disclosure provides example BSI image sensors with negatively-biased isolation structures and example methods of forming the BSI image sensors. In some embodiments, the BSI image sensor can include an interconnect structure and an isolation structure electrically connected to a metal line of the interconnect structure. The BSI image sensor can further include a metal pad structure (e.g., an input/output (I/O) port), which can be electrically connected to the isolation structure through the metal line of the interconnect structure. The isolation structure can be supplied with a negative bias voltage from a voltage supply line electrically connected to the metal pad structure. The negative bias voltage can cause a higher concentration of holes to accumulate on the isolation structure than that achieved through the negative fixed charge of the high-k dielectric liners for recombining with the electrons trapped in the surface defects of the isolation structure and reducing or preventing current leakage through the isolation structure. In addition, the concentration of accumulated holes can be modulated by adjusting the negative bias voltage applied to the isolation structure. Thus, by relying on the negative bias voltage applied to the isolation structure through the interconnect structure for leakage current control, instead of relying on the negative fixed charge of the high-k dielectric liners, the dependence of leakage current control on the dimensions of high-k dielectric liners can be eliminated, and the efficiency of the BSI image sensor can be improved.

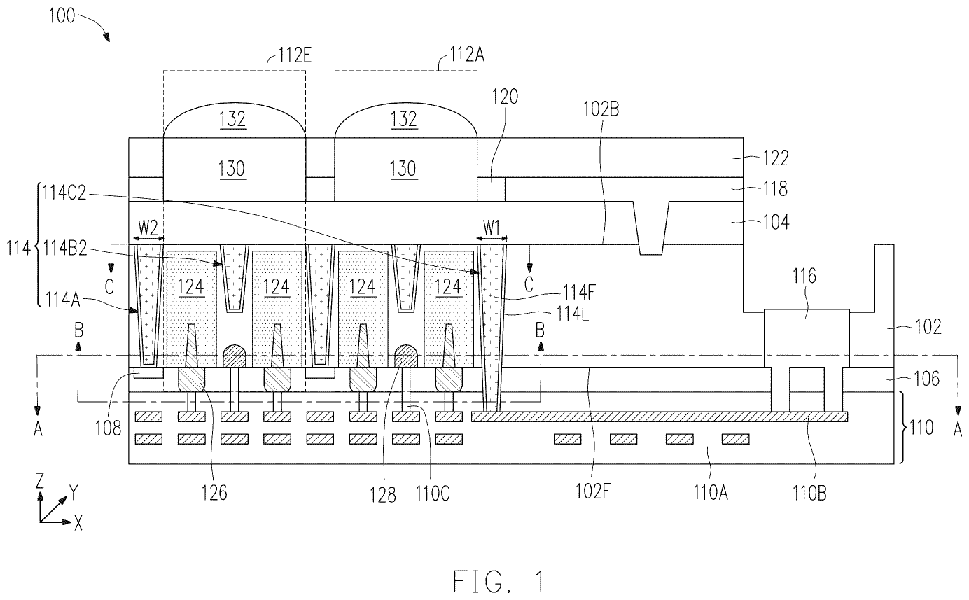

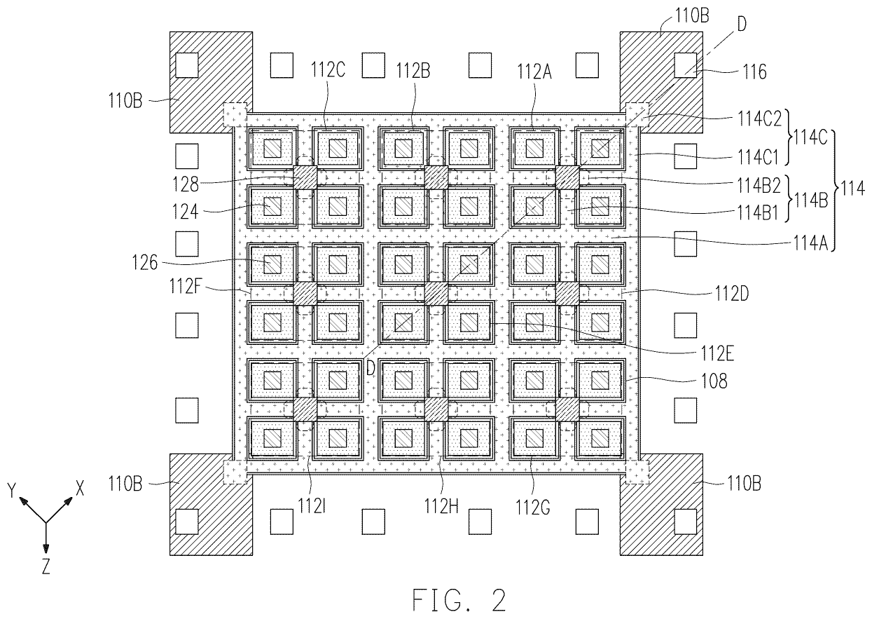

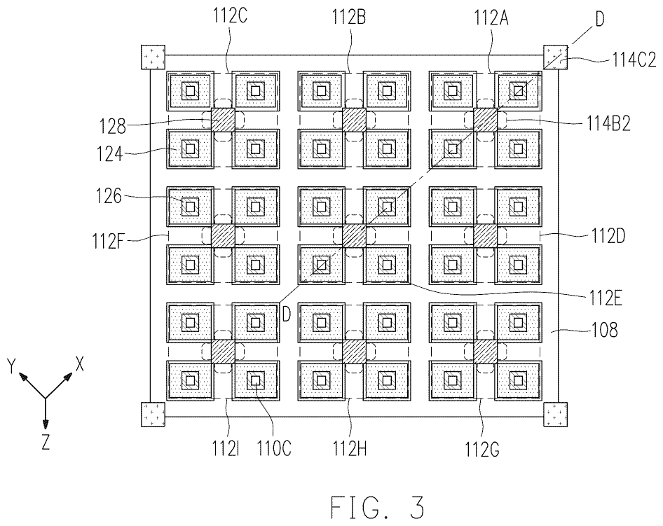

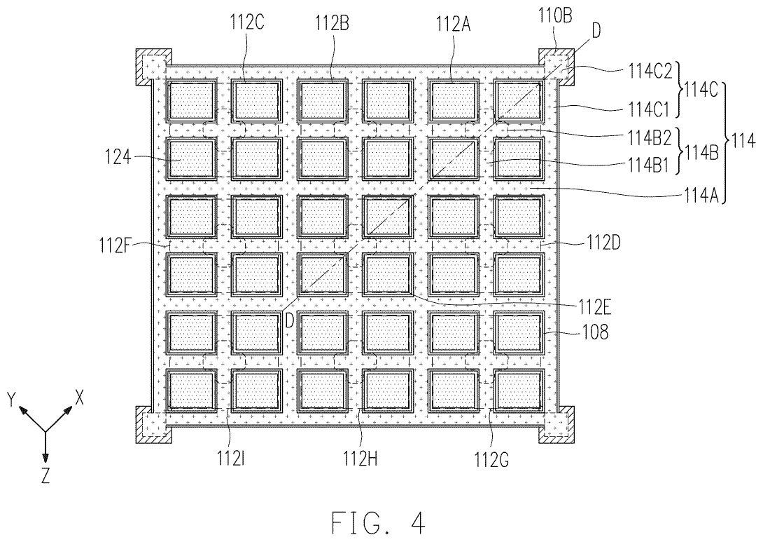

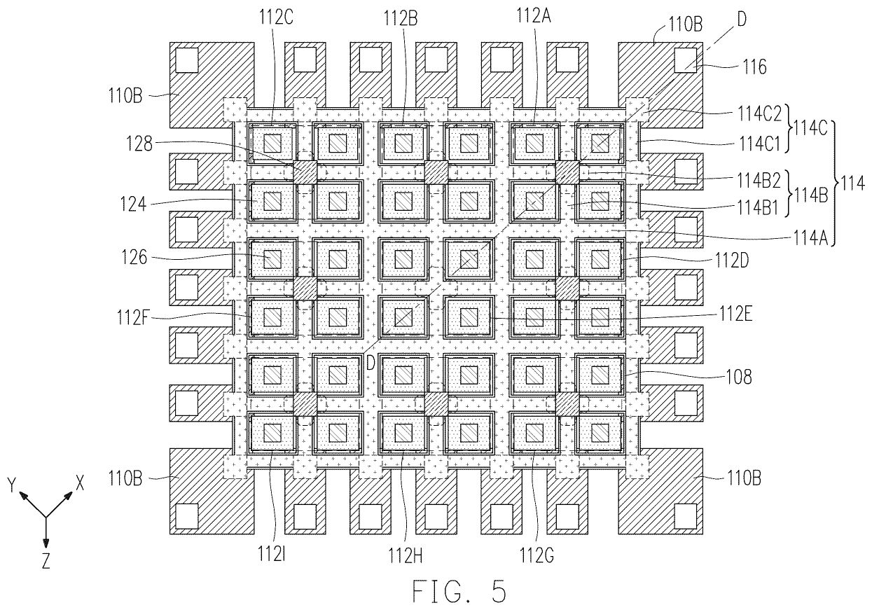

FIG. 1 illustrates a vertical cross-sectional view of a BSI image sensor 100 (also referred to as an “optical device 100”) along an XZ-plane, according to some embodiments. FIG. 2 illustrates a horizontal cross-sectional view of BSI image sensor 100 along an XY-plane and along line A-A of FIG. 1, according to some embodiments. FIG. 3 illustrates a horizontal cross-sectional view of BSI image sensor 100 along an XY-plane and along line B-B of FIG. 1, according to some embodiments. FIG. 4 illustrates a horizontal cross-sectional view of BSI image sensor 100 along an XY-plane and along line C-C of FIG. 1, according to some embodiments. FIGS. 5-7 illustrate different horizontal cross-sectional views of BSI image sensor 100 along XY-planes and along line A-A of FIG. 1, according to some embodiments. In some embodiments, FIG. 1 can be a vertical cross-sectional view of BSI image sensor 100 along line D-D of FIGS. 2-7. FIGS. 2-7 illustrate horizontal cross-sectional views of BSI image sensor 100 with additional structures that are not visible in FIG. 1 or that are not shown in FIG. 1 for simplicity. The discussion of elements in FIGS. 1-7 with the same annotations applies to each other, unless mentioned otherwise.

Referring to FIGS. 1-7, in some embodiments, BSI image sensor 100 can include (i) a substrate 102 having a back-side surface 102B and a front-side surface 102F, (ii) an anti-reflective coating (ARC) layer 104 disposed on back-side surface 102B, (iii) an interlayer dielectric (ILD) layer 106 disposed on front-side surface 102F of substrate 102, (iv) an etch stop layer (ESL) 108 disposed on front-side surface 102F of substrate 102 and in ILD layer 106, (v) an interconnect structure 110 disposed on ILD layer 106, (vi) an array of pixel structures 112A-112I disposed in substrate 102, (vii) an isolation structure 114 (also referred to as a “DTI structure 114”), (viii) metal pad structures 116, (ix) a grounding layer 118 disposed on ARC layer 104, (x) metal grid structures 120, and (xi) a passivation layer 122 disposed on metal grid structures 120 and ground layer 118. Substrate 102 and ILD layer 106 are not shown in FIGS. 2-7 for simplicity. Though nine pixel structures 112A-112I are shown in FIGS. 2-7, BSI image sensor 100 can have any number of pixel structures arranged in a one-dimensional array or a two-dimensional array. Metal pad structures 116 are not shown in FIGS. 4-7 for simplicity.

In some embodiments, substrate 102 can include a semiconductor material, such as silicon (Si), germanium (Ge), silicon germanium (SiGe), a silicon-on-insulator (SOI) structure, and a combination thereof. Further, substrate 102 can be doped with p-type dopants (e.g., boron, indium, aluminum, or gallium) or n-type dopants (e.g., phosphorus or arsenic).

In some embodiments, ARC layer 104 can be disposed on back-side surface 102B of substrate 102 to prevent incident radiation from being reflected away from pixel structures 112A-112I. In some embodiments, anti-reflective coating layer 104 can include a high-k dielectric material, such as hafnium oxide (HfO₂), tantalum pentoxide (Ta₂O₅), zirconium dioxide (ZrO₂), aluminum oxide (Al₂O₃), and any other suitable high-k dielectric material. In some embodiments, ILD layer 106 and passivation layer 122 can include a dielectric material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and any other suitable dielectric material. In some embodiments, ILD layer 106 and passivation layer 122 can include the same dielectric material or a dielectric material different from each other. In some embodiments, ESL 108 can include a dielectric material, such as SiN, silicon carbide (SiC), and any other suitable dielectric nitride or carbide material. The portions of a top surface of ESL 108 that are non-overlapping with isolation structure 114 is visible in the cross-sectional views of FIGS. 2 and 4-7 and a bottom surface of ESL 108 is visible in the cross-sectional view of FIG. 3.

Interconnect structure 110 can be disposed on ILD layer 106 and can electrically connect elements of pixel structures 112A-112I to elements of signal processing components (not shown) underlying interconnect structure 110. In addition, interconnect structure 110 can electrically connect isolation structure 114 to one or more metal pad structures 116, as described in detail below. In some embodiments, interconnect structure 110 can include (i) an inter-metal dielectric (IMD) layer 110A, (ii) metal lines 110B disposed in IMD layer 110A, and (iii) metal vias 110C disposed in IMD layer 110A. In some embodiments, IMD layer 110A can include a low-k dielectric material, such as SiOC, SiCN, and SiOCN. In some embodiments, metal lines 110B and metal vias 110C can include a conductive material, such as copper (Cu), tungsten (W), ruthenium (Ru), aluminum (Al), other suitable conductive materials, and a combination thereof. The layout of metal lines 110B and metal vias 110C are exemplary and not limiting and other layout variations of metal lines 110B and metal vias 110C are within the scope of this disclosure.

In some embodiments, each of pixel structures 112A-112I can include (i) four radiation-sensing devices 124 (also referred to as “radiation sensing regions 124”), (ii) a transfer gate structure 126 on each radiation-sensing devices 124, (iii) a floating diffusion region 128, (iv) a color filter 130, and (v) a micro-lens 132. Radiation-sensing devices 124 can be disposed in substrate 102. In some embodiments, radiation-sensing devices 124 can include an epitaxial semiconductor layer having silicon, germanium, silicon germanium, or other semiconductor materials in the III-V group, such as gallium arsenide, gallium phosphide, indium phosphide, and gallium nitride depending on the radiation wavelength of interest. For example, an epitaxial silicon layer can be used for visible light applications (e.g., between about 380 nm to about 740 nm) and an epitaxial germanium layer can be used for infrared applications (e.g., for wavelengths between about 940 nm and about 1550 nm). An epitaxial silicon germanium layer can be used for wavelengths between visible radiation and infrared radiation. In some embodiments, each of radiation-sensing devices 124 can include a photodiode. Top surfaces (also referred to as “radiation-sensing surfaces”) of radiation-sensing devices 124 can be substantially coplanar with back-side surface 102F of substrate 106 and top surface of isolation structure 114. The top surfaces of radiation-sensing devices 124 can detect the radiation entering through back-side surface 102B of substrate 102. The photons of the detected radiation can generate electron-hole pairs, which can be subsequently converted into electrical signals.

In some embodiments, transfer gate structures 126 can be disposed on back surfaces of radiation-sensing devices 124 and in ILD layer 106. Transfer gate structures 126 are not visible in the cross-sectional view of FIG. 4. Each of transfer gate structures 126 can include a gate dielectric layer (not shown) disposed on the back surfaces of radiation-sensing devices 124 and a gate metal layer (not shown) disposed on the gate dielectric layer. Transfer gate structures 126 can control the transfer of electrons from radiation-sensing devices 124 to other elements of BSI image sensor 100, such as signal processing components (not shown).

In some embodiments, floating diffusion regions 128 (also referred to as “floating diffusion nodes 128”) can be disposed in substrate 102 and can be non-overlapping with radiation-sensing devices 124, as shown in FIGS. 1-3. Floating diffusion regions 128 are not visible in the cross-sectional view of FIG. 4. In some embodiments, floating diffusion regions 128 can include doped regions disposed in substrate 102. In some embodiments, the doped regions can include n-type dopants when substrate 102 includes p-type dopants. In some embodiments, each floating diffusion region 128 can be disposed in a substrate region between the four radiation-sensing devices 124 of a corresponding one of pixel structures 112A-112I, as shown in FIGS. 2 and 3. With such placement of floating diffusion regions 128, the function of one floating diffusion region 128 can be shared by four radiation-sensing devices 124. Each floating diffusion regions 128 can store charges (e.g., electrons) transferred by transfer gate structures 126 from radiation-sensing devices 124 of a corresponding one of pixel structures 112A-112I.

In some embodiments, color filters 130 can be disposed in passivation layer 122 and top surfaces of color filters 130 can be substantially coplanar with a top surface of passivation layer 122. In some embodiments, each color filter 130 can overlap the entire radiation-sensing surfaces of the underlying four radiation-sensing devices 124 in a corresponding one of pixel structures 112A-112I. In some embodiments, color filters 130 can include a polymeric material. In some embodiments, micro-lens 132 can be disposed on color filters 130 and each micro-lens 132 can overlap the entire radiation-sensing surfaces of the underlying four radiation-sensing devices 124 in a corresponding one of pixel structures 112A-112I.

In some embodiments, isolation structure 114 can be disposed in substrate 102 and can surround each of pixel structures 112A-112I and each radiation-sensing devices 124, as shown in FIGS. 1, 2, and 4. Isolation structure 114 can be configured to prevent or minimize electrical and/or optical cross-talk between radiation-sensing devices 124 of each pixel structures 112A-112I and between pixel structures 112A-112I to improve the quantum efficiency of BSI image sensor 100, as described in detail below. In some embodiments, isolation structure 114 can include (i) a conductive fill layer 114F and (ii) a high-k dielectric liner 114L (shown in FIG. 1; not shown in FIGS. 2-7 for simplicity) surrounding conductive fill layer 114F. Conductive fill layer 114F can block photons in from straying between radiation-sensing devices 124. In some embodiments, conductive fill layer 114F can include a metallic material, such as W, Al, Ru, and cobalt (Co), a conductive oxide, polysilicon, or other suitable conductive material. High-k dielectric liner 114L can electrically isolate conductive fill layer 114F from substrate 102 and/or pixel structures 112A-112I. In some embodiments, high-k dielectric layer 114L can include a high-k material, such as HfO₂, Al₂O₃, any other suitable high-k dielectric material, and a combination thereof.

In some embodiments, isolation structure 114 can include (i) an inter-pixel isolation portion 114A, (ii) intra-pixel isolation portions 114B, and (iii) a peripheral isolation portion 114C. In some embodiments, inter-pixel isolation portion 114A can be disposed between adjacent pixel structures in the array of pixel structures 112A-112I and can electrically and/or optically isolate pixel structures 112A-112I from each other. In some embodiments, inter-pixel isolation portion 114A can extend vertically along a Z-axis from back-side surface 102B of substrate 102 to front-side surface 102F, as shown in FIG. 1.

In some embodiments, inter-pixel isolation portion 114A can have (i) a tapered cross-sectional profile along a vertical cross-sectional plane (e.g., an XZ-plane), as shown in FIG. 1, (ii) a top surface substantially coplanar with back-side surface 102B of substrate 102, as shown in FIG. 1, (iii) a bottom surface substantially coplanar with front-side surface 102F of substrate 102, as shown in FIG. 1, (iv) a width of the top surface greater than a width of the bottom surface along a vertical cross-sectional plane (e.g., an XZ-plane), as shown in FIG. 1, (v) the top surface in physical contact with a bottom surface of ARC layer 104, as shown in FIG. 1, (vi) the bottom surface in physical contact with the top surface of ESL 108, as shown in FIG. 1, (vii) a vertical height along a Z-axis greater than a vertical height of radiation-sensing devices 124, as shown in FIG. 1, and (viii) sub-portion with rectangular-shaped cross-sectional profiles along a horizontal cross-sectional plane (e.g., an XY-plane) and between adjacent pixel structures in the array of pixel structures 112A-112I, as shown in FIGS. 2 and 4-7.

Referring to FIG. 1, in some embodiments, high-k dielectric liner 114L of inter-pixel isolation portion 114A can be disposed on sidewalls and a bottom surface of conductive fill layer 114F of inter-pixel isolation portion 114A and not disposed on a top surface of conductive fill layer 114F of inter-pixel isolation portion 114A. In some embodiments, the top surface of conductive fill layer 114F of inter-pixel isolation portion 114A can be in physical contact with the bottom surface of ARC layer 104. In some embodiments, a top surface of high-k dielectric liner 114L of inter-pixel isolation portion 114A can be in physical contact with the bottom surface of ARC layer 104 and a bottom surface of high-k dielectric liner 114L of inter-pixel isolation portion 114A can be in physical contact with the top surface of ESL 108.

In some embodiments, each intra-pixel isolation portion 114B can be disposed between radiation-sensing devices 124 in a corresponding one of pixel structures 112A-112I and can electrically and/or optically isolate radiation-sensing devices 124 from each other. In some embodiments, each intra-pixel isolation portion 114B can include (i) a first isolation sub-portion 114B1 (not visible in the cross-sectional view of FIG. 1, shown in FIGS. 2 and 4-7) and (ii) a second isolation sub-portion 114B2, as shown in FIGS. 1-7. In some embodiments, similar to inter-pixel isolation portion 114A, first isolation sub-portion 114B1 can (i) extend vertically along a Z-axis from back-side surface 102B of substrate 102 to front-side surface 102F, (ii) have a top surface in physical contact with the bottom surface of ARC layer 104, and (iii) have a bottom surface in physical contact with the top surface of ESL 108.

In some embodiments, second isolation sub-portion 114B2 can extend vertically along a Z-axis from back-side surface 102B of substrate 102 and can be suspended over floating diffusion region 128, as shown in FIG. 1. Unlike, inter-pixel isolation portion 114A and first isolation sub-portion 114B1, second isolation sub-portion 114B2 does not extend to front-side surface 102F of substrate 102. In some embodiments, each second isolation sub-portion 114B2 can have (i) a tapered cross-sectional profile along a vertical cross-sectional plane (e.g., an XZ-plane), as shown in FIG. 1, (ii) a top surface substantially coplanar with back-side surface 102B of substrate 102, as shown in FIG. 1, (iii) a width of the top surface greater than a width of a bottom surface of along a vertical cross-sectional plane (e.g., an XZ-plane), as shown in FIG. 1, (iv) the top surface in physical contact with a bottom surface of ARC layer 104, as shown in FIG. 1, (v) a vertical height along a Z-axis smaller than the vertical height of inter-pixel isolation portion 114A, as shown in FIG. 1, and (vi) a plus-shaped cross-sectional profile along a horizontal cross-sectional plane (e.g., an XY-plane), as shown with dashed lines in FIGS. 2-7.

Referring to FIG. 1, in some embodiments, high-k dielectric liner 114L of second isolation sub-portion 114B2 can be disposed on sidewalls and a bottom surface of conductive fill layer 114F of second isolation sub-portion 114B2 and not disposed on a top surface of conductive fill layer 114F of second isolation sub-portion 114B2. In some embodiments, the top surface of conductive fill layer 114F of second isolation sub-portion 114B2 can be in physical contact with the bottom surface of ARC layer 104. In some embodiments, a top surface of high-k dielectric liner 114L of second isolation sub-portion 114B2 can be in physical contact with the bottom surface of ARC layer 104 and a bottom surface of high-k dielectric liner 114L of second isolation sub-portion 114B2 can be in physical contact with substrate 102.

In some embodiments, peripheral isolation portion 114C can surround the array of pixel structures 112A-112I. In some embodiments, peripheral isolation portion 114C can include (i) a ring-shaped sub-portion 114C1 (not visible in the cross-sectional view of FIG. 1, shown in FIGS. 2 and 4-7) and (ii) protruding sub-portions 114C2, as shown in FIGS. 1-7. In some embodiments, ring-shaped sub-portion 114C1 can have a ring-shaped cross-sectional profile along a horizontal cross-sectional plane (e.g., an XY-plane), as shown in FIGS. 2 and 4-7. In some embodiments, one protruding sub-portion 114C2 can extend out of each corner of ring-shaped sub-portion 114C1. In some embodiments, each protruding sub-portion 114C2 can be disposed on and electrically connected to a corresponding one of metal lines 110B in interconnect structure 110. In some embodiments, one or more of protruding sub-portions 114C2 can be supplied with a negative bias voltage through the corresponding metal lines 110B to negatively bias isolation structure 114. Negative biasing of isolation structure 114 can cause holes to accumulate on isolation structure 114, which can recombine with any trapped electrons present in surfaces defects of isolation structure 114 and minimize or prevent current leakage through isolation structure 114, as discussed above.

Referring to FIG. 1, in some embodiments, each protruding sub-portion 114C2 can (i) be disposed in substrate 102, ILD layer 106, and IMD layer 110A, (ii) extend vertically along a Z-axis from back-side surface 102B of substrate 102 to a top surface of metal line 110B in IMD layer 110A, (iii) have a tapered cross-sectional profile along a vertical cross-sectional plane (e.g., an XZ-plane), (iv) have a top surface substantially coplanar with back-side surface 102B of substrate 102, (v) have a width of the top surface greater than a width of a bottom surface along a vertical cross-sectional plane (e.g., an XZ-plane), (vi) have the top surface in physical contact with a bottom surface of ARC layer 104, (vii) have the bottom surface in physical contact with the top surface of metal line 110B, (viii) have a vertical height along a Z-axis greater than the vertical height of inter-pixel isolation portion 114A, and (ix) have a width W1 of the top surface greater than a width W2 of the top surface of inter-pixel isolation portion 114A along an X-axis.

Referring to FIG. 1, in some embodiments, high-k dielectric liner 114L of protruding sub-portion 114C2 can be disposed on sidewalls of conductive fill layer 114F of protruding sub-portion 114C2 and not disposed on top and bottom surfaces of conductive fill layer 114F of protruding sub-portion 114C2. In some embodiments, the top surface of conductive fill layer 114F of protruding sub-portion 114C2 can be in physical contact with the bottom surface of ARC layer 104, and the bottom surface of conductive fill layer 114F of protruding sub-portion 114C2 can be in physical contact with the top surface of metal line 110B. In some embodiments, a top surface of high-k dielectric liner 114L of protruding sub-portion 114C2 can be in physical contact with the bottom surface of ARC layer 104, and a bottom surface of high-k dielectric liner 114L of protruding sub-portion 114C2 can be in physical contact with the top surface of metal line 110B.

In some embodiments, each metal pad structure 116 can be disposed on a corresponding one of metal lines 110B in interconnect structure 110. In some embodiments, at least one of metal pad structures 116 can be electrically connected to one of protruding sub-portion 114C2 through a common metal line 110B, as shown in FIGS. 1 and 2. The one or more metal pad structures 116 that share metal lines 110B with protruding sub-portion 114C2 can be electrically connected to voltage supply lines to supply negative bias voltage to protruding sub-portion 114C2. In some embodiments, metal pad structures 116 and grounding layer 118 can include a metal, such as W, Al, Ru, Co, and other suitable metals. In some embodiments, metal grid structures 120 can be disposed on ARC layer 104 and between adjacent color filters 130.

In some embodiments, instead of the cross-sectional view of FIG. 2, BSI image sensor 100 can have the cross-sectional view of FIG. 5 along line A-A of FIG. 1, with additional structures that are not visible in FIG. 1 or that are not shown in FIG. 1 for simplicity. The discussion of peripheral isolation portion 114C of FIGS. 1-4 applies to peripheral isolation portion 114C of FIG. 5, unless mentioned otherwise. In some embodiments, instead of one protruding sub-portion 114C2 extending out of each corner of ring-shaped sub-portion 114C1, an array of protruding sub-portions 114C2 can extend out of each side of ring-shaped sub-portion 114C1, as shown in FIG. 5. In some embodiments, each protruding sub-portions 114C2 can be disposed on and electrically connected to a corresponding one of metal lines 110B in interconnect structure 110, as shown in FIG. 5. In some embodiments, each protruding sub-portion in the array of protruding sub-portions 114C2 can share a metal line 110B with a corresponding one of metal pad structures in the array of metal pad structures 116 surrounding pixel structures 112A-112A, as shown in FIG. 5. In some embodiments, one or more of protruding sub-portions 114C2 can be supplied with a negative bias voltage through the corresponding metal lines 110B and metal pad structures 116 to negatively bias isolation structure 114.

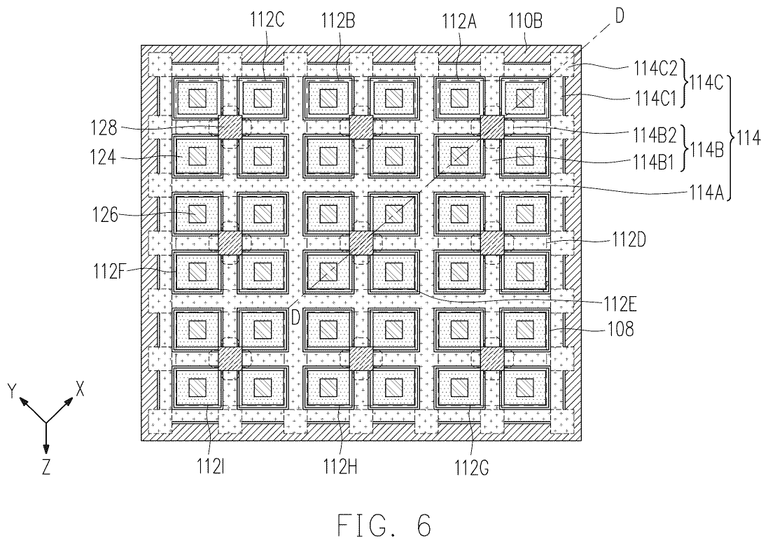

In some embodiments, instead of the cross-sectional views of FIGS. 2 and 5, BSI image sensor 100 can have the cross-sectional view of FIG. 6 along line A-A of FIG. 1, with additional structures that are not visible in FIG. 1 or that are not shown in FIG. 1 for simplicity. The discussion of peripheral isolation portion 114C of FIG. 5 applies to peripheral isolation portion 114C of FIG. 6, unless mentioned otherwise. Metal pad structures 116 are not shown in FIG. 6 for simplicity. In some embodiments, instead of each protruding sub-portion 114C2 being electrically connected to a different metal line 110B of interconnect structure 110, the array of protruding sub-portions 114C2 can share a metal 110B, as shown in FIG. 6 and can be electrically connected to one or more metal pad structures 116 through the shared metal line 110B. In some embodiments, metal line 110B of FIG. 6 can have a ring-shaped cross-sectional profile along a horizontal cross-sectional plane (e.g., an XY-plane), as shown in FIG. 6.

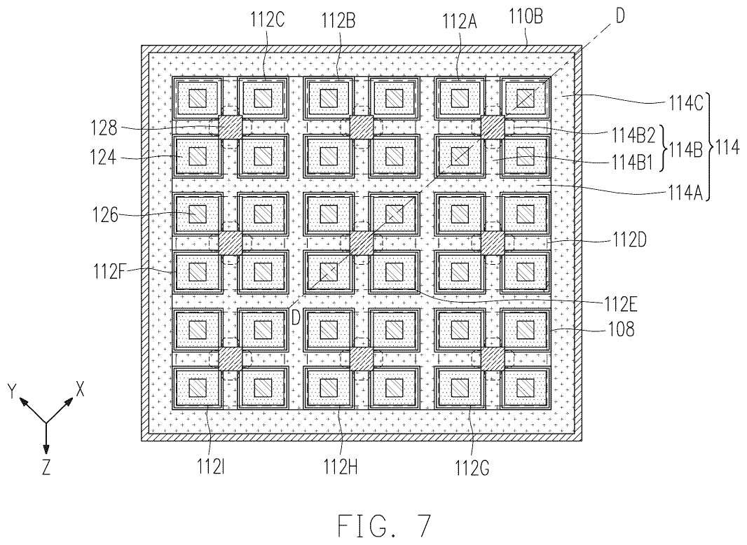

In some embodiments, instead of the cross-sectional views of FIGS. 2, 5, and 6, BSI image sensor 100 can have the cross-sectional view of FIG. 7 along line A-A of FIG. 1, with additional structures that are not visible in FIG. 1 or that are not shown in FIG. 1 for simplicity. The discussion of peripheral isolation portion 114C and metal line 110B of FIG. 6 applies to peripheral isolation portion 114C and metal line 110B of FIG. 7, unless mentioned otherwise. Metal pad structures 116 are not shown in FIG. 7 for simplicity. Referring to FIG. 7, in some embodiments, peripheral isolation portion 114C can have a ring-shaped structure without any protruding sub-portions 114C2. In some embodiments, peripheral isolation portion 114C can be disposed on and electrically connected to the ring-shaped metal line 110B.

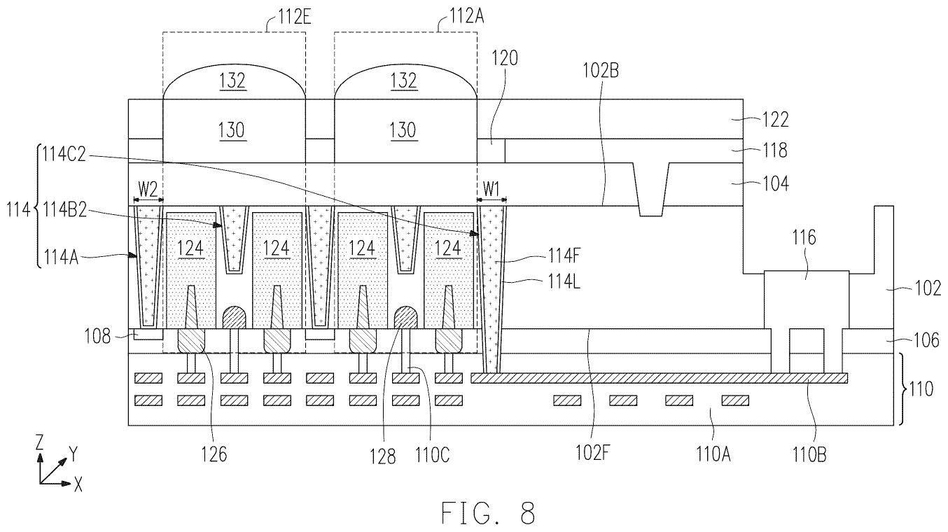

In some embodiments, instead of the cross-sectional view of FIG. 1, BSI image sensor 100 can have the cross-sectional view of FIG. 8. The discussion of BSI image sensor 100 of FIG. 1 applies to BSI image sensor 100 of FIG. 8, unless mentioned otherwise. Referring to FIG. 8, in some embodiments, the bottom surface of high-k dielectric liner 114L of protruding sub-portions 114C2 can be in physical contact with ILD layer 106, instead of the top surface of metal line 110B shown in FIG. 1. In some embodiments, a bottom portion of conductive fill layer 114F of protruding sub-portions 114C2 can be surrounded by and in physical contact with ILD layer 106 and IMD layer 110B.

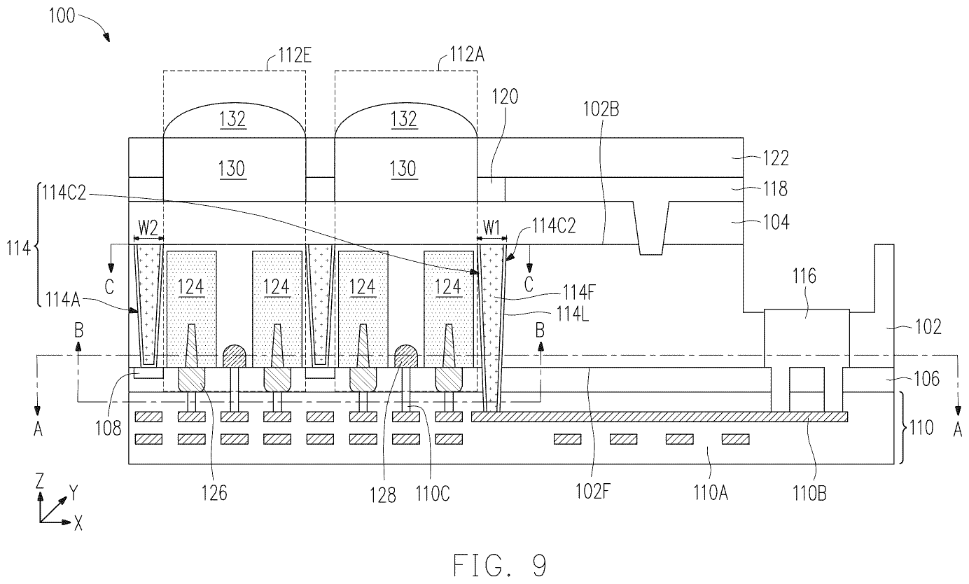

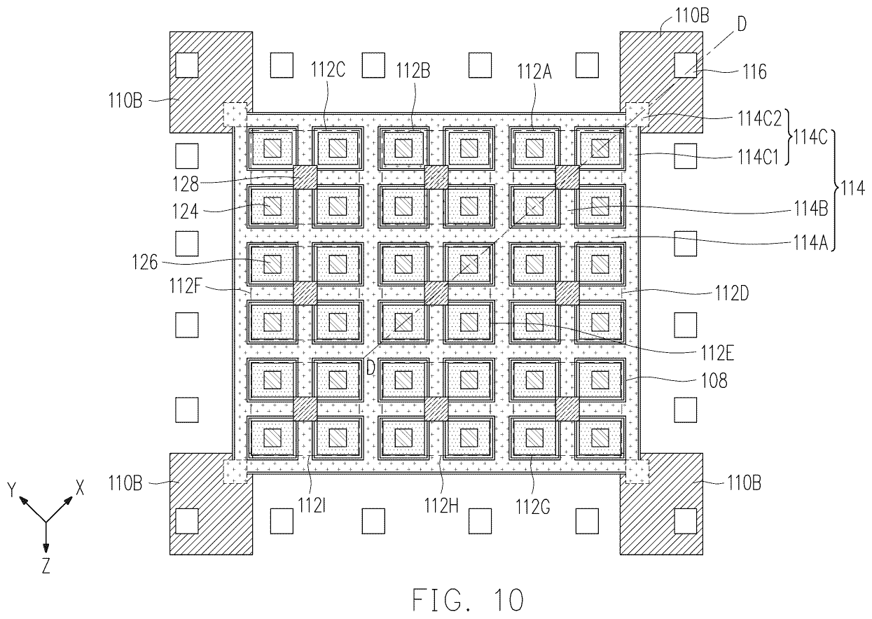

FIG. 9 illustrates a vertical cross-sectional view of a BSI image sensor 900 (also referred to as an “optical device 900”) along an XZ-plane, according to some embodiments. FIG. 10 illustrates a horizontal cross-sectional view of BSI image sensor 900 along an XY-plane and along line A-A of FIG. 9, according to some embodiments. The discussion of BSI image sensor 100 applies to BSI image sensor 900, unless mentioned otherwise. The discussion of elements in FIGS. 1-10 with the same annotations applies to each other, unless mentioned otherwise. In some embodiments, unlike BSI image sensor 100, intra-pixel isolation portions 114B of BSI image sensor 900 do not include second isolation sub-portions 114B2 suspended over floating diffusion regions 128, as shown in FIGS. 9 and 10.

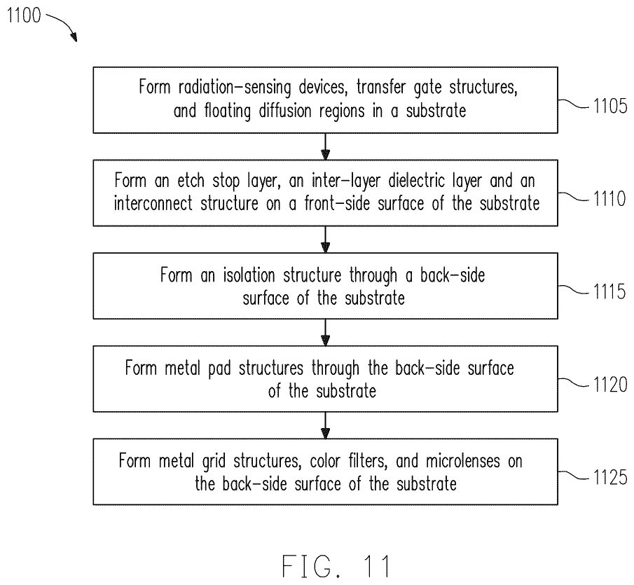

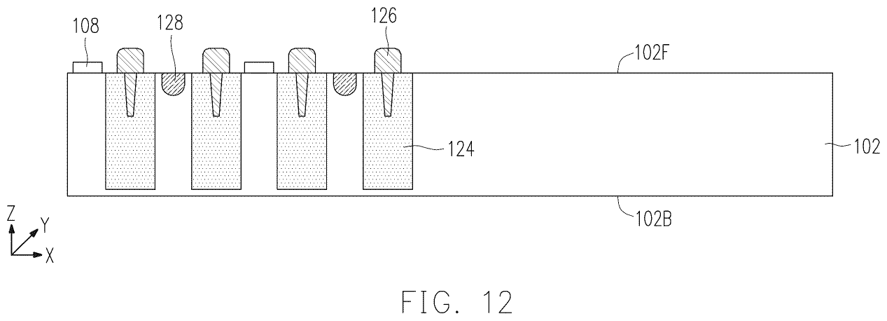

FIG. 11 is a flow diagram of an example method 1100 for fabricating BSI image sensor 100 as shown in FIGS. 1-7, according to some embodiments. For illustrative purposes, the operations illustrated in FIG. 11 will be described with reference to the example fabrication process for fabricating BSI image sensor 100 as illustrated in FIGS. 12-19. FIGS. 12-19 are cross-sectional views of BSI image sensor 100 along line A-A of FIG. 1 at various stages of its fabrication, according to some embodiments. Operations can be performed in a different order or not performed depending on specific applications. It should be noted that method 1100 may not produce a complete BSI image sensor 100. Accordingly, it is understood that additional processes can be provided before, during, and after method 1100, and that some other processes may only be briefly described herein. The discussion of elements in FIGS. 1-7 and 12-19 with the same annotations applies to each other, unless mentioned otherwise.

Referring to FIG. 11, in operation 1105, radiation-sensing devices, transfer gate structures, and floating diffusion regions are formed. For example, as described with reference to FIG. 12, radiation-sensing devices 124, transfer gate structures 126, and floating diffusion regions 128 are formed. In some embodiments, radiation-sensing devices 124 can be formed in substrate 102, which can be followed by the formation of transfer gate structures 126 on substrate 102, as shown in FIG. 12. The formation of transfer gate structures 126 can be followed by performing a doping process in substrate 102 through back-side surface 102B of substrate 102 to form floating diffusion regions 128, as shown in FIG. 12.

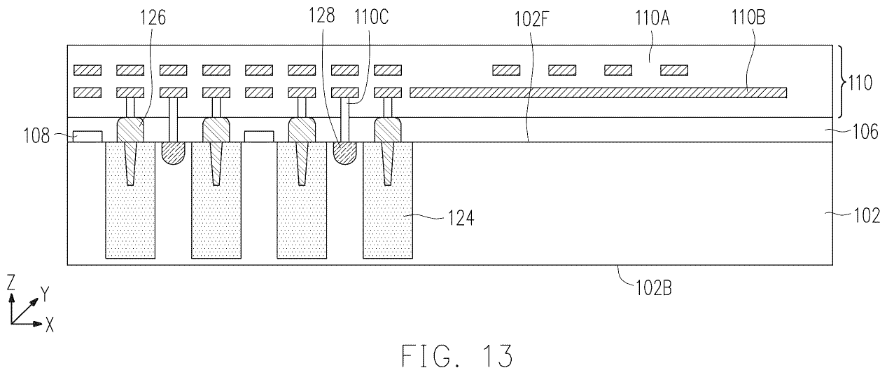

Referring to FIG. 11, in operation 1110, an ESL layer, and ILD layer, and an interconnect structure are formed on a front-side surface of the substrate. For example, as described with reference to FIGS. 12 and 13, ESL 108, ILD layer 106, and interconnect structure 110 are formed on front-side surface 102F of substrate 102. In some embodiments, ESL 108 can be formed on front-side surface 102F of substrate 102 after the formation of diffusion regions 128 in operation 1105. The formation of ESL 108 can be followed by depositing ILD layer 106 on the structure of FIG. 12 and forming interconnect structure 110 on ILD layer 106 to form the structure of FIG. 13.

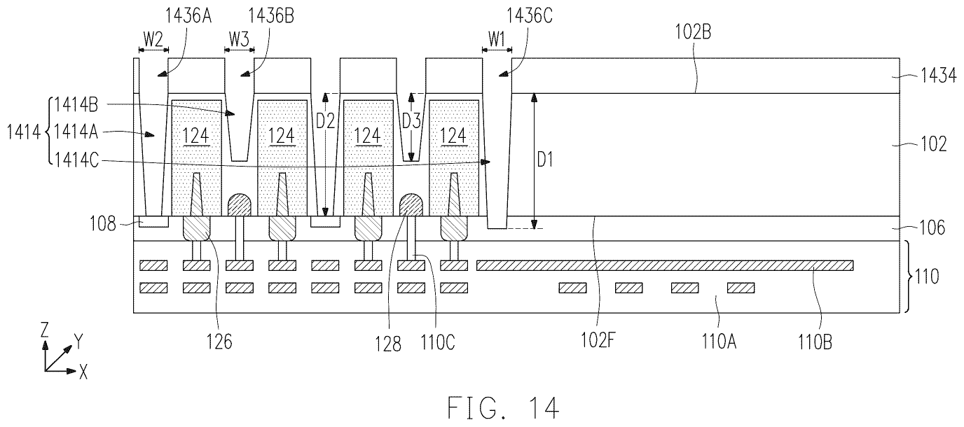

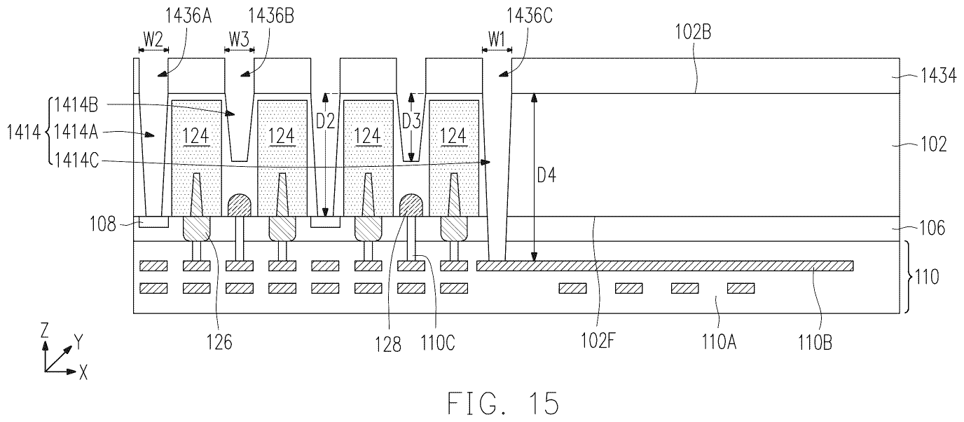

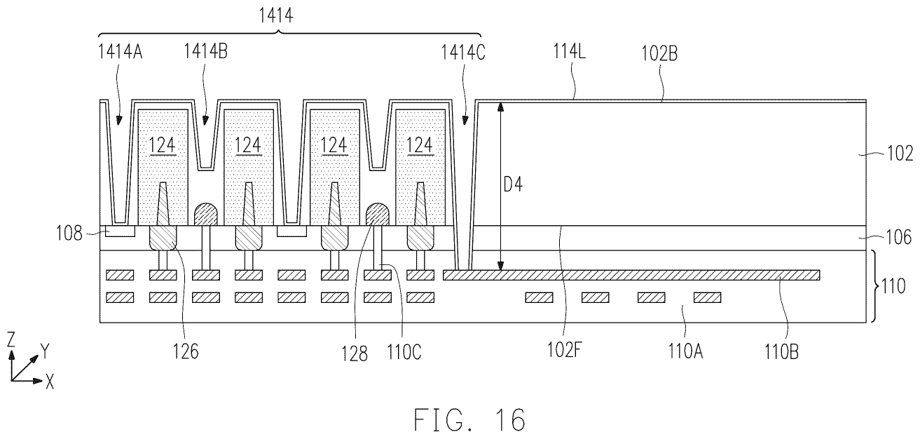

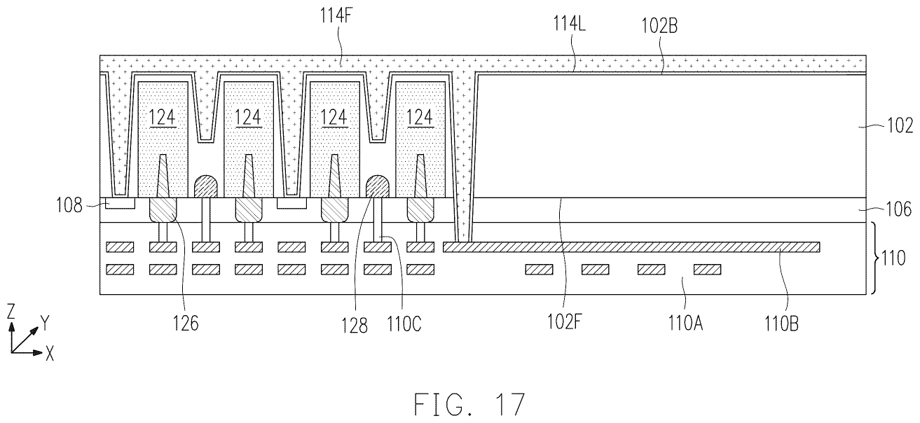

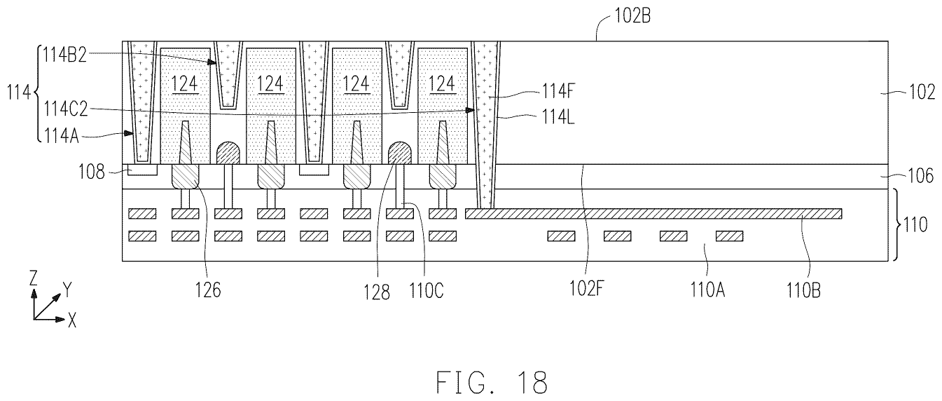

Referring to FIG. 11, in operation 1115, an isolation structure is formed through a back-side surface of the substrate. For example, as described with reference to FIGS. 14-18, isolation structure 114 is formed through back-side surface 102B of substrate 102. In some embodiments, the formation of isolation structure 114 can include sequential operations of (i) forming a patterned masking layer 1434 with openings 1436A, 1436B, and 1436C on the structure of FIG. 13, as shown in FIG. 14, (ii) performing a first etching process on back-side surface 102B of substrate 102 through patterned masking layer 1434 using an etching gas with a higher etching selectivity for the semiconductor material (e.g., Si) of substrate 102 than the dielectric material (e.g., SiO₂) of ILD layer 106 to form an isolation trench 1414 with trench portions 1414A, 1414B, and 1414C, as shown in FIG. 14, (iii) performing a second etching process on the structure of FIG. 14 using an etching gas with a higher etching selectivity for the dielectric materials (e.g., SiO₂) of ILD layer 106 and IMD layer 110A than the semiconductor material (e.g., Si) of substrate 102 to extend the depth of trench portion 1414C from D1 to D4 and to expose the top surface of metal line 110B in trench portion 1414C, as shown in FIG. 15, (iv) removing patterned masking layer 1434, (v) depositing high-k dielectric liner 114L on the structure of FIG. 15 after removing patterned masking layer 1434 to form the structure of FIG. 16, (vi) depositing conductive fill layer 114F on the structure of FIG. 16 to form the structure of FIG. 17, and (vii) performing a chemical mechanical polishing (CMP) process on the structure of FIG. 17 to substantially coplanarize top surfaces of high-k dielectric liner 114L and conductive fill layer 114F with back-side surface 102B of substrate 102, as shown in FIG. 18.

Referring to FIG. 14, as width W1 of opening 1436C is greater than width W2 of opening 1436A, the etching rate for forming trench portion 1414C through opening 1436C is faster than the etching rate for forming trench portion 1414A through opening 1436A. As a result, depth D1 of trench portion 1414C is greater than depth D2 of trench portion 1414A. Similarly, as width W2 of opening 1436A is greater than width W3 of opening 1436B, the etching rate for forming trench portion 1414A through opening 1436A is faster than the etching rate for forming trench portion 1414B through opening 1436B. As a result, depth D2 of trench portion 1414A is greater than depth D3 of trench portion 1414C. In some embodiments, during the first and second etching processes, ESL 108 can control the depth of trench portion 1414A to D2 and can prevent ILD layer 106 from being etched through trench portion 1414A. Referring to FIG. 16, in some embodiments, depositing high-k dielectric liner 114L can include selectively depositing the high-k dielectric material of high-k dielectric liner 114L on the exposed surfaces of substrate 102, ILD layer 106, ESL 108, and IMD layer 110B in isolation trench 1414 using an atomic layer deposition (ALD) process without depositing on the exposed top surface of metal line 110B.

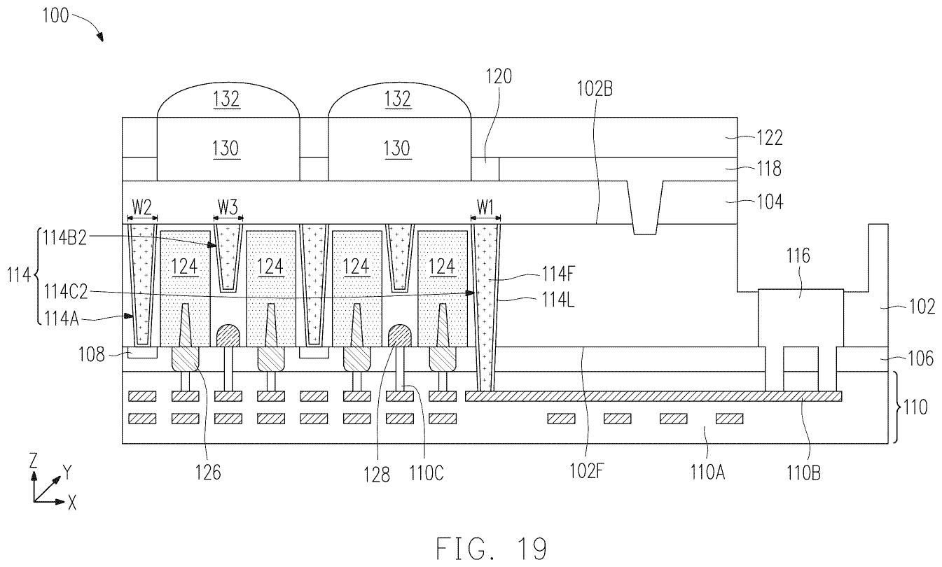

Referring to FIG. 11, in operation 1120, metal pad structures are formed through the back-side surface of the substrate. For example, as shown in FIG. 19, metal pad structure 116 is formed on the top surface of metal line 110B through back-side surface 102B of substrate 102, ILD layer 106, and IMD layer 110B.

Referring to FIG. 11, in operation 1125, metal grid structures, color filters, and microlenses are formed on the back-side surface of the substrate. For example, as shown in FIG. 19, metal grid structures 120, color filters 130, and microlenses are formed on back-side surface 102B of substrate 102.

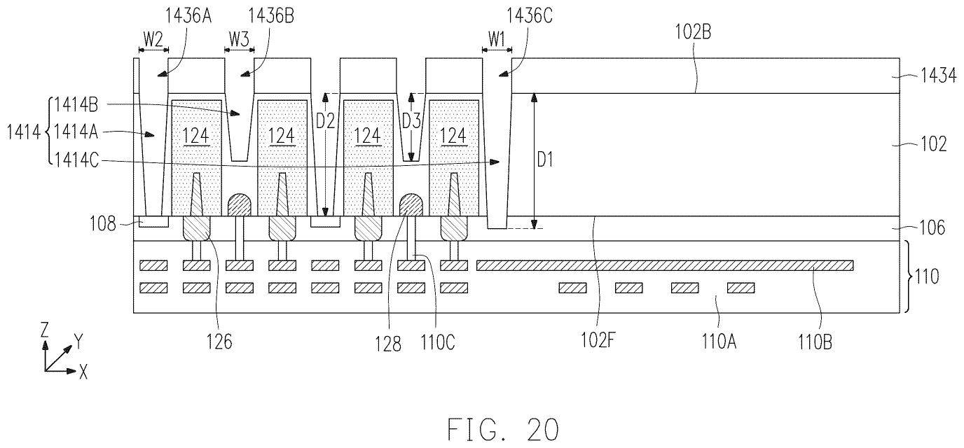

In some embodiments, BSI image sensor 100 with the cross-sectional view of FIG. 8 can be formed using method 1100, except operation 1115 is performed as described below with reference to FIGS. 20-24, instead of that described above with reference to FIGS. 14-18. The discussion of elements in FIGS. 1-8 and 12-24 with the same annotations applies to each other, unless mentioned otherwise.

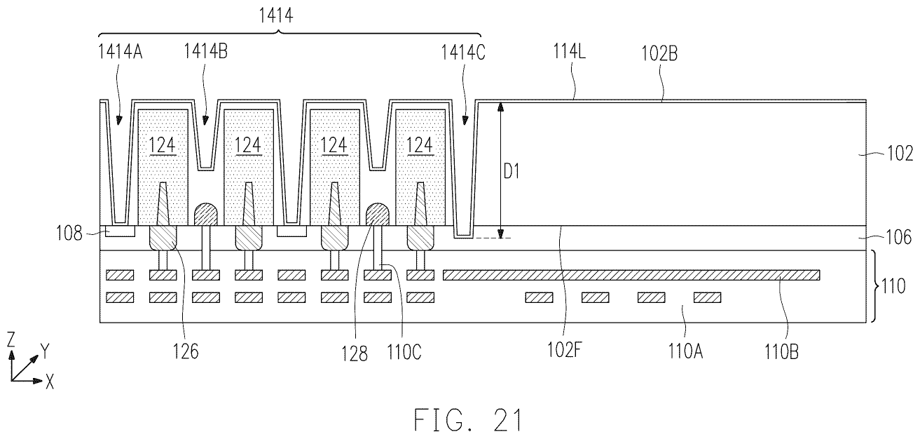

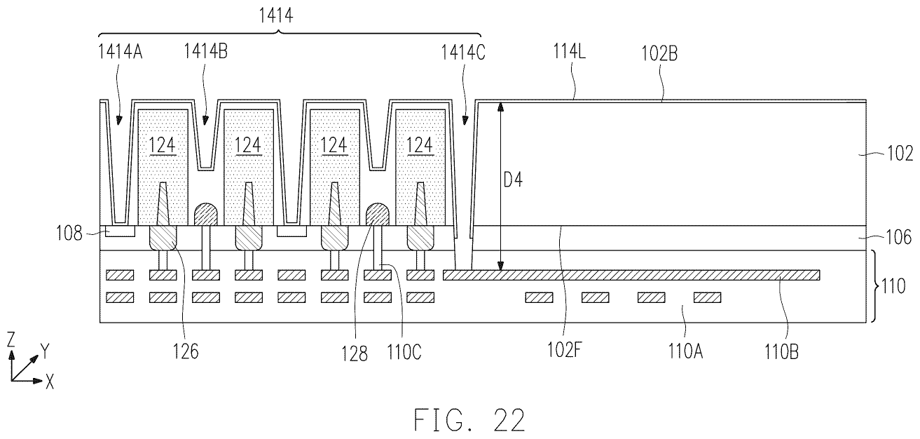

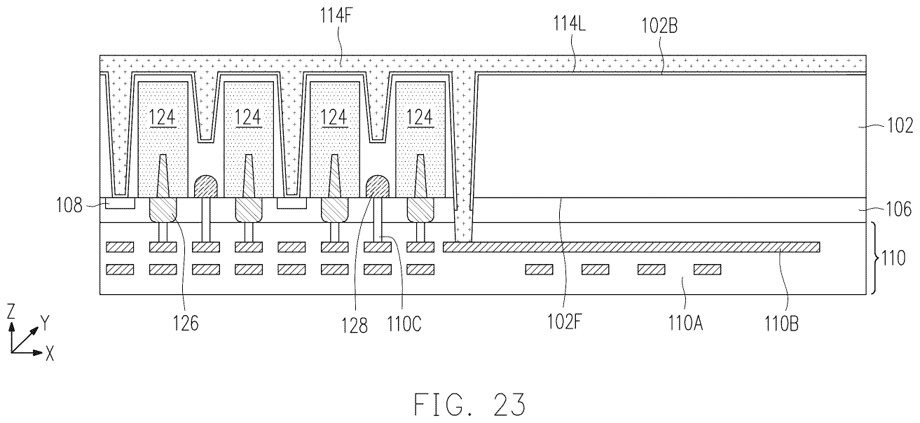

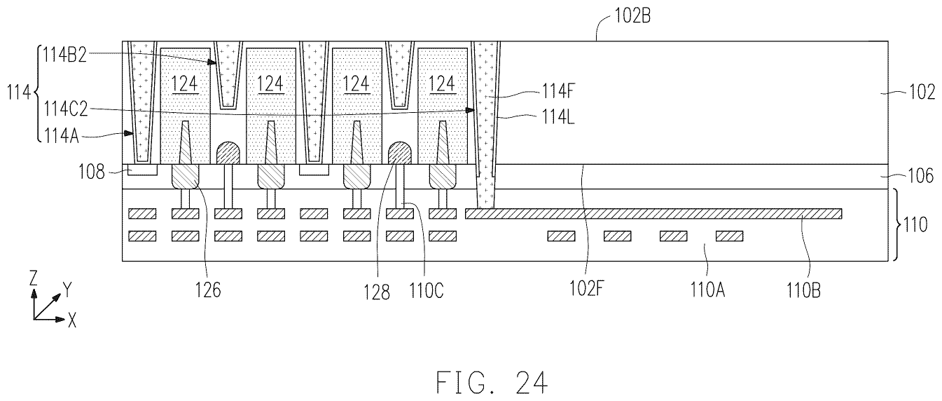

Referring to FIG. 11, in operation 1115, an isolation structure is formed through a back-side surface of the substrate. For example, as described with reference to FIGS. 20-24, isolation structure 114 is formed through back-side surface 102B of substrate 102. In some embodiments, the formation of isolation structure 114 can include sequential operations of (i) forming a patterned masking layer 1434 with openings 1436A, 1436B, and 1436C on the structure of FIG. 13, as shown in FIG. 20, (ii) performing a first etching process on back-side surface 102B of substrate 102 through patterned masking layer 1434 using an etching gas with a higher etching selectivity for the semiconductor material (e.g., Si) of substrate 102 than the dielectric material (e.g., SiO₂) of ILD layer 106 to form an isolation trench 1414 with trench portions 1414A, 1414B, and 1414C, as shown in FIG. 20, (iii) removing patterned masking layer 1434, (iv) depositing high-k dielectric liner 114L on the structure of FIG. 20 after removing patterned masking layer 1434 to form the structure of FIG. 21, (v) performing a second etching process on the structure of FIG. 21 using an etching gas with a higher etching selectivity for the dielectric materials (e.g., SiO₂) of ILD layer 106 and IMD layer 110A than the semiconductor material (e.g., Si) of substrate 102 to etch bottom portion of high-k dielectric layer 114L in trench portion 1414C, to extend the depth of trench portion 1414C from D1 to D4, and to expose the top surface of metal line 110B in trench portion 1414C, as shown in FIG. 22, (vi) depositing conductive fill layer 114F on the structure of FIG. 22 to form the structure of FIG. 23, and (vii) performing a CMP process on the structure of FIG. 23 to substantially coplanarize top surfaces of high-k dielectric liner 114L and conductive fill layer 114F with back-side surface 102B of substrate 102, as shown in FIG. 24. Operations 1120 and 1125 can be performed on the structure of FIG. 24 as described above with reference to FIG. 19 to form BSI image sensor 100 with the cross-sectional view of FIG. 8.

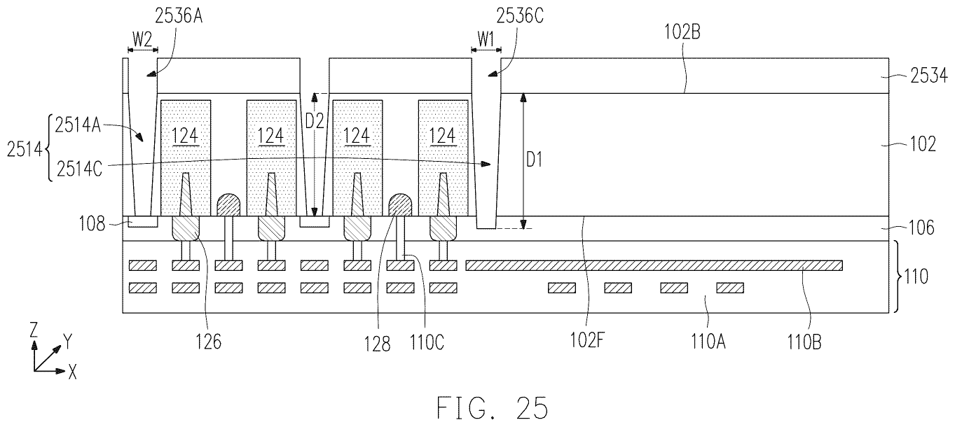

In some embodiments, BSI image sensor 900 with the cross-sectional view of FIG. 9 can be formed using method 1100, except operation 1115 is performed as described below with reference to FIGS. 25-29, instead of that described above with reference to FIGS. 14-18 and 20-24. The discussion of elements in FIGS. 1-10 and 12-29 with the same annotations applies to each other, unless mentioned otherwise.

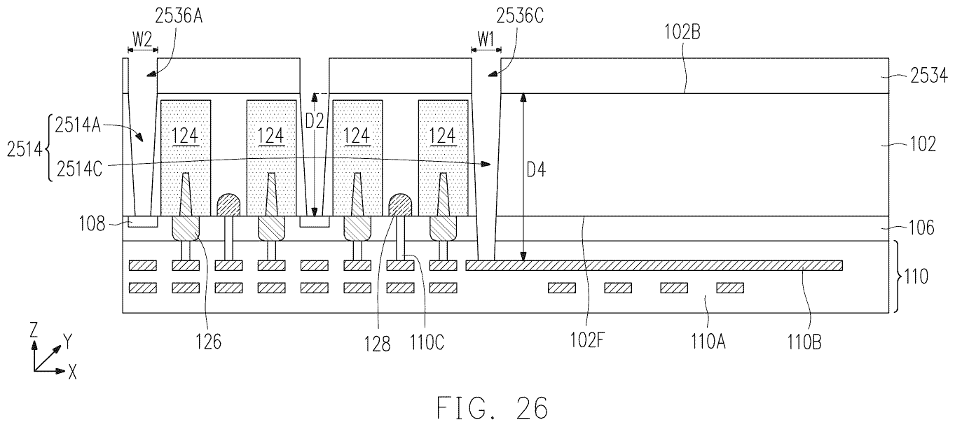

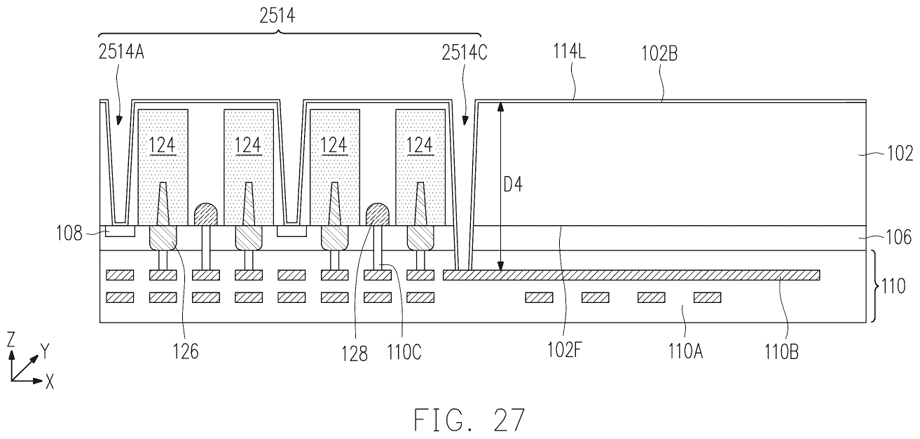

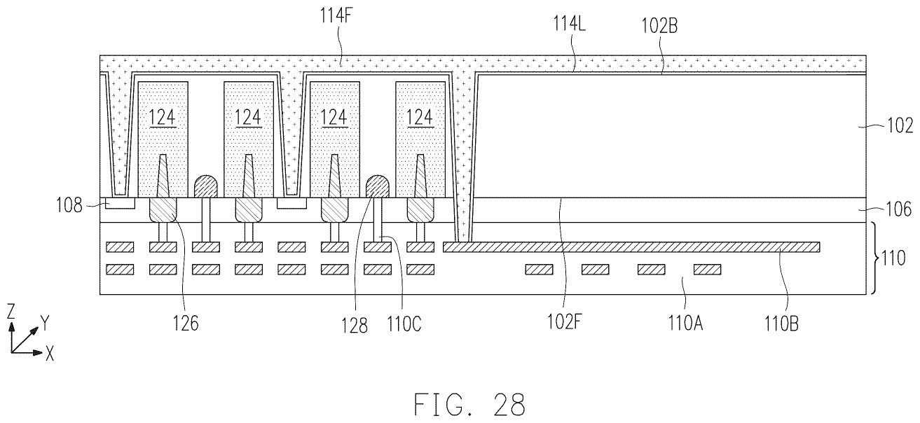

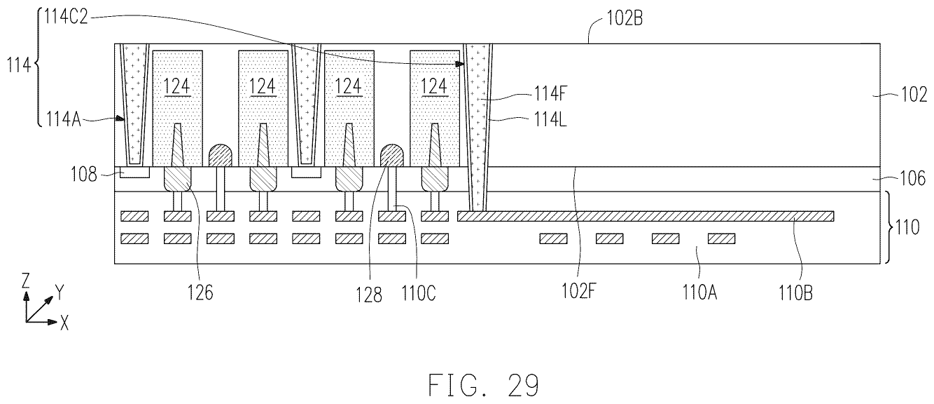

Referring to FIG. 11, in operation 1115, an isolation structure is formed through a back-side surface of the substrate. For example, as described with reference to FIGS. 25-29, isolation structure 114 of BSI image sensor 900 is formed through back-side surface 102B of substrate 102. In some embodiments, the formation of isolation structure 114 can include sequential operations of (i) forming a patterned masking layer 2534 with openings 2536A and 2536C on the structure of FIG. 13, as shown in FIG. 26, (ii) performing a first etching process on back-side surface 102B of substrate 102 through patterned masking layer 2534 using an etching gas with a higher etching selectivity for the semiconductor material (e.g., Si) of substrate 102 than the dielectric material (e.g., SiO₂) of ILD layer 106 to form an isolation trench 2514 with trench portions 2514A and 2514C, as shown in FIG. 25, (iii) performing a second etching process on the structure of FIG. 25 using an etching gas with a higher etching selectivity for the dielectric materials (e.g., SiO₂) of ILD layer 106 and IMD layer 110A than the semiconductor material (e.g., Si) of substrate 102 to extend the depth of trench portion 2514C from D1 to D4 and to expose the top surface of metal line 110B in trench portion 2514C, as shown in FIG. 26, (iv) removing patterned masking layer 2534, (v) depositing high-k dielectric liner 114L on the structure of FIG. 26 after removing patterned masking layer 2534 to form the structure of FIG. 27, (vi) depositing conductive fill layer 114F on the structure of FIG. 27 to form the structure of FIG. 28, and (vii) performing a CMP process on the structure of FIG. 28 to substantially coplanarize top surfaces of high-k dielectric liner 114L and conductive fill layer 114F with back-side surface 102B of substrate 102, as shown in FIG. 29. Operations 1120 and 1125 can be performed on the structure of FIG. 29 as described above with reference to FIG. 19 to form BSI image sensor 900 with the cross-sectional view of FIG. 9.

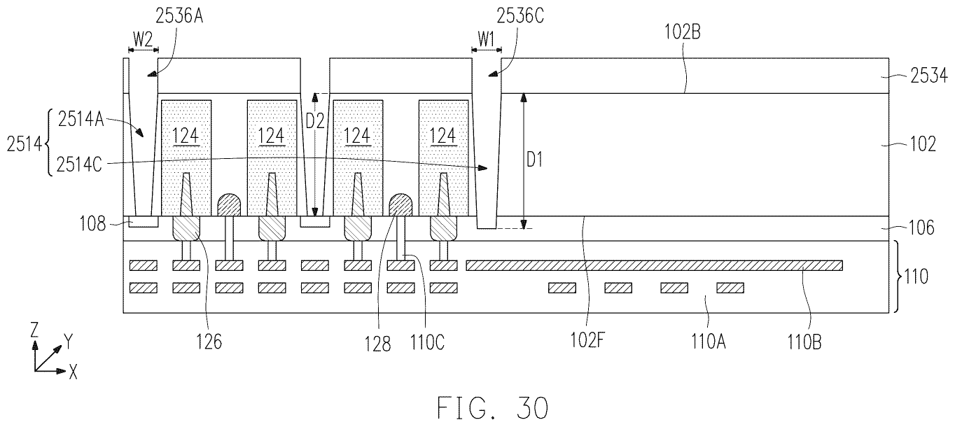

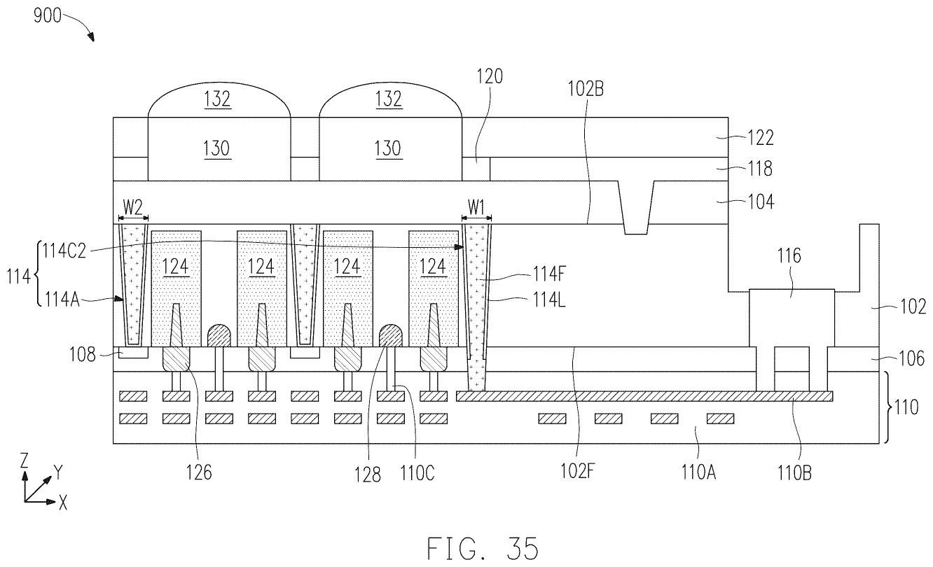

In some embodiments, BSI image sensor 900 with the cross-sectional view of FIG. 35 can be formed using method 1100, except operation 1115 is performed as described below with reference to FIGS. 30-35, instead of that described above with reference to FIGS. 14-18 and 20-29. The discussion of elements in FIGS. 1-10 and 12-35 with the same annotations applies to each other, unless mentioned otherwise.

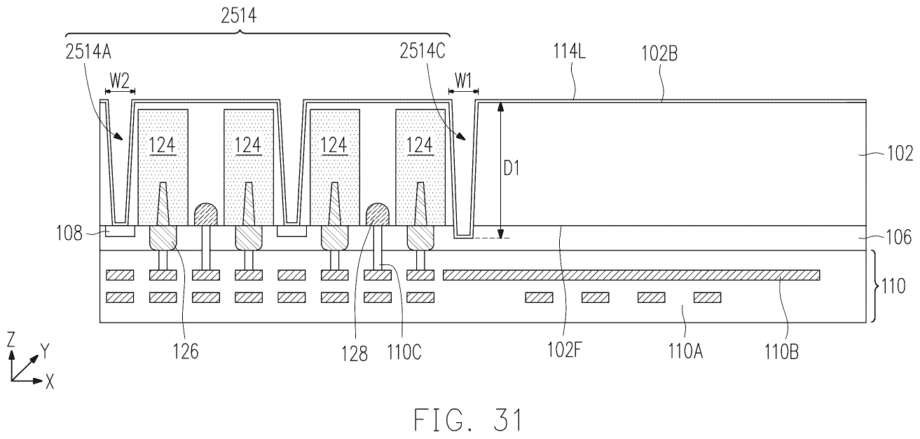

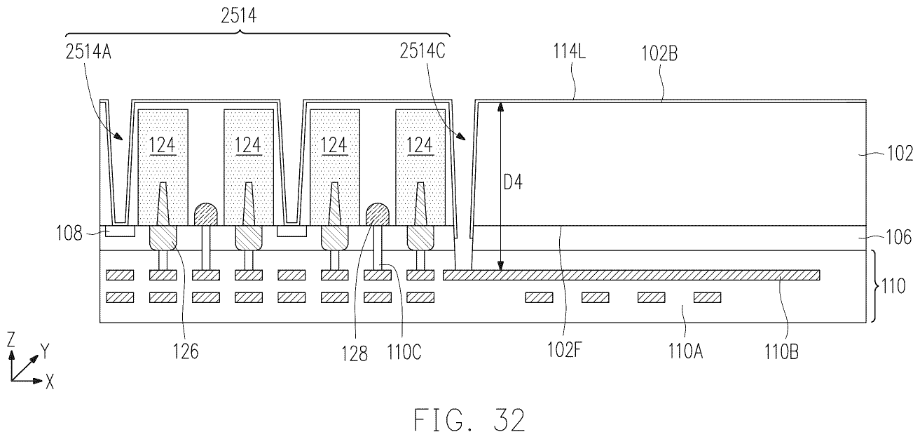

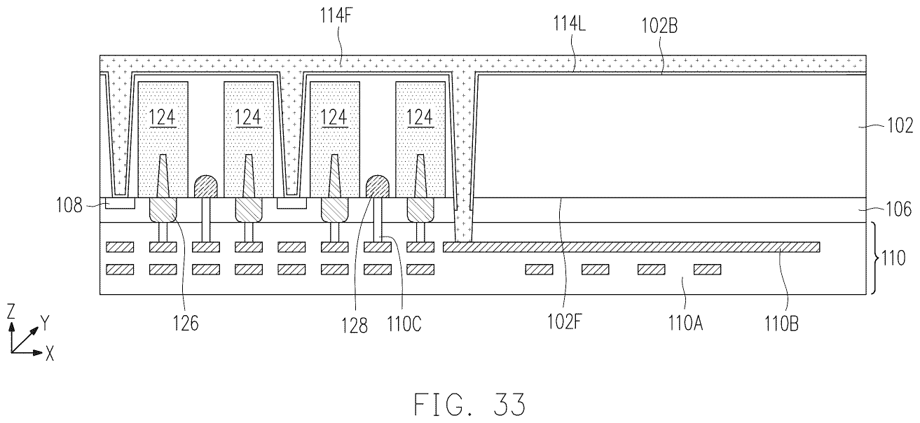

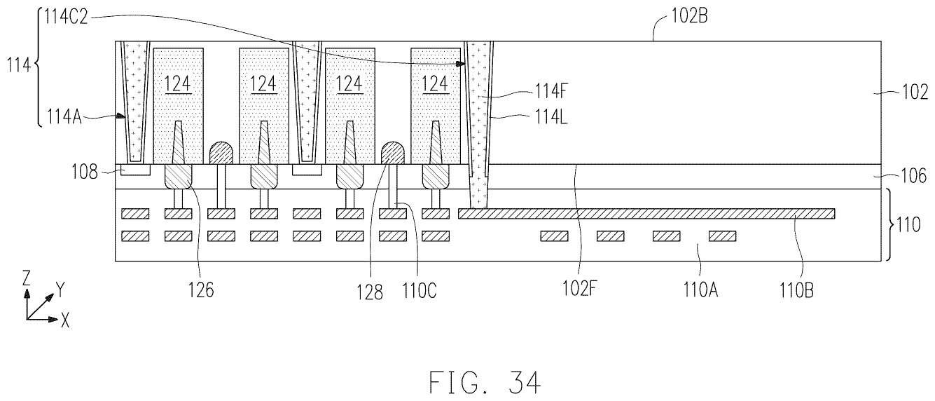

Referring to FIG. 11, in operation 1115, an isolation structure is formed through a back-side surface of the substrate. For example, as described with reference to FIGS. 30-35, isolation structure 114 is formed through back-side surface 102B of substrate 102. In some embodiments, the formation of isolation structure 114 can include sequential operations of (i) forming a patterned masking layer 2534 with openings 2536A and 2536C on the structure of FIG. 13, as shown in FIG. 30, (ii) performing a first etching process on back-side surface 102B of substrate 102 through patterned masking layer 2534 using an etching gas with a higher etching selectivity for the semiconductor material (e.g., Si) of substrate 102 than the dielectric material (e.g., SiO₂) of ILD layer 106 to form an isolation trench 2514 with trench portions 2514A and 2514C, as shown in FIG. 30, (iii) removing patterned masking layer 2534, (iv) depositing high-k dielectric liner 114L on the structure of FIG. 30 after removing patterned masking layer 2534 to form the structure of FIG. 31, (v) performing a second etching process on the structure of FIG. 31 using an etching gas with a higher etching selectivity for the dielectric materials (e.g., SiO₂) of ILD layer 106 and IMD layer 110A than the semiconductor material (e.g., Si) of substrate 102 to etch bottom portion of high-k dielectric layer 114L in trench portion 2514C, to extend the depth of trench portion 2514C from D1 to D4, and to expose the top surface of metal line 110B in trench portion 2514C, as shown in FIG. 32, (vi) depositing conductive fill layer 114F on the structure of FIG. 32 to form the structure of FIG. 33, and (vii) performing a CMP process on the structure of FIG. 33 to substantially coplanarize top surfaces of high-k dielectric liner 114L and conductive fill layer 114F with back-side surface 102B of substrate 102, as shown in FIG. 34. Operations 1120 and 1125 can be performed on the structure of FIG. 34 as described above with reference to FIG. 19 to form BSI image sensor 900 with the cross-sectional view of FIG. 35.

The present disclosure provides example BSI image sensors (e.g., BSI image sensors 100 and 900) with negatively-biased isolation structures (e.g., isolation structure 1414) and example methods (e.g., method 1100) of forming the BSI image sensors. In some embodiments, the BSI image sensor can include an interconnect structure (e.g., interconnect structure 110) and an isolation structure (e.g., isolation structure 1414) electrically connected to a metal line (e.g., metal line 110B) of the interconnect structure. The BSI image sensor can further include a metal pad structure (e.g., metal pad structure 116), which can be electrically connected to the isolation structure through the metal line of the interconnect structure. The isolation structure can be supplied with a negative bias voltage from a voltage supply line electrically connected to the metal pad structure. The negative bias voltage can cause a higher concentration of holes to accumulate on the isolation structure than that achieved through the negative fixed charge of the high-k dielectric liners for recombining with the electrons trapped in the surface defects of the isolation structure and reducing or preventing current leakage through the isolation structure. In addition, the concentration of accumulated holes can be modulated by adjusting the negative bias voltage applied to the isolation structure. Thus, by relying on the negative bias voltage applied to the isolation structure through the interconnect structure for leakage current control, instead of relying on the negative fixed charge of the high-k dielectric liners, the dependence of leakage current control on the dimensions of high-k dielectric liners can be eliminated, and the efficiency of the BSI image sensor can be improved.

In some embodiments, an optical device includes a substrate with a first surface and a second surface opposite to the first surface, an array of pixel structures disposed in the substrate, an interconnect structure with a metal line disposed on the first surface of the substrate, and an isolation structure. The isolation structure includes an inter-pixel isolation portion disposed between adjacent pixel structures in the array of pixel structures and a peripheral isolation portion surrounding the array of pixel structures and disposed on the metal line of the interconnect structure.

In some embodiments, an optical device includes a substrate, first and second radiation-sensing devices disposed in the substrate, an interconnect structure with a dielectric layer disposed on the substrate and a metal line disposed in the dielectric layer, and an isolation structure. The isolation structure includes a first isolation portion disposed between the first and second radiation-sensing devices and a second isolation portion disposed on and in contact with the metal line of the interconnect structure.

In some embodiments, a method includes forming first and second radiation-sensing devices in a substrate, forming an interconnect structure with a dielectric layer and a metal line on a first surface of the substrate, performing a first etching process on a second surface of the substrate to form an isolation trench with first and second trench portions, performing a second etching process to modify the first trench portion, depositing a dielectric liner into the isolation trench, and depositing a conductive layer on the dielectric liner.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate comprising a first surface and a second surface opposite to the first surface;
an array of pixel structures disposed in the substrate;
an interconnect structure comprising a metal line disposed on the first surface of the substrate;
an isolation structure, comprising:
an inter-pixel isolation portion disposed between adjacent pixel structures in the array of pixel structures; and
a peripheral isolation portion surrounding the array of pixel structures and in contact with a top surface of the metal line of the interconnect structure; and
a metal pad structure in contact with the top surface of the metal line of the interconnect structure.

2. The device of claim 1, wherein the metal pad structure extends through the substrate and a dielectric layer of the interconnect structure and is configured to supply a negative bias voltage to the peripheral isolation portion.

3. The device of claim 1, wherein the peripheral isolation portion comprises:
a first sub-portion comprising a ring-shaped cross-sectional profile along a horizontal cross-sectional plane; and
a second sub-portion protruding from a corner of the first sub-portion and disposed on the metal line of the interconnect structure.

4. The device of claim 1, wherein the peripheral isolation portion comprises a sub-portion that extends vertically from the second surface of the substrate to the top surface of the metal line of the interconnect structure.

5. The device of claim 1, wherein the peripheral isolation portion comprises a sub-portion comprising a dielectric liner and a conductive layer, and
wherein a bottom surface of the conductive layer is in contact with the top surface of the metal line of the interconnect structure.

6. The device of claim 1, wherein a height of the peripheral isolation portion is greater than a height of the inter-pixel isolation portion.

7. The device of claim 1, wherein a width of the peripheral isolation portion is greater than a width of the inter-pixel isolation portion.

8. The device of claim 1, further comprising an etch stop layer disposed on the first surface of the substrate, wherein the inter-pixel isolation portion extends vertically from the second surface of the substrate to a top surface of the etch stop layer.

9. The device of claim 1, wherein the isolation structure further comprises an intra-pixel isolation portion disposed between radiation-sensing regions in a pixel structure in the array of pixel structures.

10. The device of claim 1, further comprising an anti-reflective coating layer disposed on the second surface of the substrate, wherein a top surface of the peripheral isolation portion is in contact with a bottom surface of the anti-reflective coating layer, and wherein a bottom surface of the peripheral isolation portion is in contact with the top surface of the metal line of the interconnect structure.

11. A device, comprising:
a substrate;
first and second radiation-sensing regions disposed in the substrate;
an interconnect structure comprising a dielectric layer disposed on the substrate and a metal line disposed in the dielectric layer; and
an isolation structure, comprising:
a first isolation portion disposed between the first and second radiation-sensing regions; and
a second isolation portion in contact with the metal line of the interconnect structure.

12. The device of claim 11, wherein the second isolation portion comprises:
a first sub-portion comprising a ring-shaped cross-sectional profile along a horizontal cross-sectional plane; and
a second sub-portion protruding from a corner of the first sub-portion and disposed on the metal line of the interconnect structure.

13. The device of claim 11, further comprising a floating diffusion region disposed in the substrate, wherein the first isolation portion is suspended over the floating diffusion region.

14. The device of claim 11, wherein the first isolation portion comprises a plus-shaped cross-sectional profile along a horizontal cross-sectional plane.

15. The device of claim 11, wherein the second isolation portion comprises a sub-portion that extends vertically through the substrate and into the dielectric layer.

16. The device of claim 11, wherein a width of the second isolation portion is greater than a width of the first isolation portion.

17. A method, comprising:
forming first and second radiation-sensing regions in a substrate;
forming an interconnect structure with a dielectric layer and a metal line on a first surface of the substrate;
performing a first etching process on a second surface of the substrate to form an isolation trench with first and second trench portions;
performing a second etching process to modify the first trench portion;
depositing a dielectric liner into the isolation trench; and
depositing a conductive layer on the dielectric liner.

18. The method of claim 17, wherein performing the first etching process on a second surface of the substrate comprises forming the first trench portion with a first depth and the second trench portion with a second depth that is less than the first depth.

19. The method of claim 17, wherein performing the second etching process to modify the first trench portion comprises etching the dielectric layer of the interconnect structure to extend a depth of the first trench portion to the metal line of the interconnect structure.

20. The method of claim 17, wherein depositing the dielectric liner into the isolation trench comprises depositing a high-k dielectric layer on sidewalls of the isolation trench without depositing the high-k dielectric layer on the metal line of the interconnect structure.
